(19) United States
(12) Patent Application Publication
(10) Pub. No.: US 2008/0006522 A1
(43) Pub. Date: Jan. 10, 2008

(54) Method of producing metal-oxide film

(75) Inventor: Kaoru Yamakawa, Kawasaki (JP)

Correspondence Address: Patrick G. Burns,Esq.;GREER, BURNS & CRAIN, LTD., Suite 2500, 300 South Wacker Dr., Chicago, IL, 60606, US

(73) Assignee: FUJITSU LIMITED

(21) Appl. No.: 11/600,459

(22) Filed: Nov. 16, 2006

(30) Foreign Application Priority Data
Jul. 7, 2006 (JP) 2006-188281

(51) Int. Cl. C23C 14/32

(52) U.S. Cl. 204/192.1

(57) ABSTRACT

The method is capable of making a thickness of the metal oxide-film on an edge section in a surface of a work nearly equal to that on a flat section therein so as to uniformly form the metal oxide-film can be on the surface of the work. The method of producing a metal-oxide film comprises the steps of: introducing a sputtering gas and oxygen into a spattering chamber, in which a metal member and a work are mutually faced; and applying DC voltage to the metal member and applying high-frequency negative voltage to the work so as to oxidize the metal member and form a sputtered film on a surface of the work.

### BACKGROUND OF THE INVENTION

The present invention relates to a method of producing a metal-oxide film, e.g., alumina film, on a surface of a work by sputtering.

Conventionally, metal-oxide films, e.g., alumina film, have been used in many fields.

For example, in a thin film magnetic head, an alumina film is used as a gap layer between “an upper shielding layer or a lower shielding layer” and “a read-element and terminals connected to the read-element”.

A partial sectional view of a thin film magnetic head, in which an alumina film is used as a gap layer, is shown in FIG. 2. The thin film magnetic head shown in FIG. 2 comprises: a GMR element 30 acting as a read-element; base layers 36 and hard films 38 sandwiching the GMR element 30 from the both sides; read-terminals 40 respectively formed on the hard films 38; a gap layer 42 made of alumina, the gap layer coating the GMR element 30 and the read-terminals 40; an upper shielding layer 44 formed on the gap layer 42; a gap layer 34 formed under the GMR element 30 and the base layer 36; and a lower shielding layer 32 formed under the gap layer 34.

A conventional method of producing a gap layer made of alumina is disclosed in Japanese Patent Gazette No. 10-105925. According to a paragraph 0028 and FIG. 1 of the Japanese patent gazette, the gap layer made of alumina film is formed on a lower shielding layer by the steps of: applying negative bias voltage to an entire substrate, on which the alumina film will be formed; and performing alumina-target sputtering.

Surfaces of works, on which alumina films will be formed, are not always flat. For example, as shown in FIG. 2, angular edge sections 46, etc. are formed on surfaces of the read-terminals 40. In the sputtering process, it is difficult to fully stick the alumina film on the edge sections 46, a thickness of the alumina film thereon must be thinner than that of the alumina film on a flat section. Further, the edge sections are abraded more than the flat section when an abrasion process, e.g., ion milling, etching, is performed. Therefore, the thickness of the alumina film is partially made thinner at the positions corresponding to the edge sections, so that the layers respectively located on the upper side and the lower side of the alumina film, e.g., the upper shielding layer 44 and the read-terminals 40, cannot be fully insulated.

### SUMMARY OF THE INVENTION

The present invention was conceived to solve the above described problems.

An object of the present invention is to provide a method of producing a metal-oxide film, which is capable of making a thickness of the metal oxide-film on an edge section in a surface of a work nearly equal to that on a flat section therein so as to uniformly form the metal oxide-film can be on the surface of the work.

The inventor of the present invention has formed alumina films under various conditions and found a method of uniformly form an alumina film on an edged section and a flat section in a surface of a work.

To achieve the objects, the present invention has following structures.

Namely, the method of producing a metal-oxide film comprising the steps of: introducing a sputtering gas and oxygen into a spattering chamber, in which a metal member and a work are mutually faced; and applying DC voltage to the metal member and applying high-frequency negative voltage to the work so as to oxidize the metal member and form a sputtered film on a surface of the work.

In the method, a distance between facing surfaces of the metal member and the work may be 1.8 inches or less.

In the method, the high-frequency negative voltage applied to the work may be from −10 V to −1 V.

In the method, the high-frequency negative voltage applied may be applied to the work in a floating state, in which earth of a high-frequency negative voltage source is insulated from those of a DC voltage source and a chassis.

In the method, a rotary magnet may be provided to a rear surface of the metal member, which is the opposite surface with respect to a surface facing the work, and the rotary magnet may be rotated in the applying step so as to perform a rotary magnetron sputter technique. In the method, a step-shaped section may be formed in the surface of the work.

By employing the method of the present invention, the thickness of the metal oxide-film on the edge section in the surface of the work can be made thicker or nearly equal to that on the flat section therein. Therefore, the metal oxide-film can be uniformly formed on the surface of the work.

Further, by employing the method of the present invention in a process of forming a magnetic head, the thickness of the metal oxide-film, e.g., alumina film used as a gap layer, on edge sections can be made thicker or nearly equal to that on flat sections. Therefore, in the edge sections, a read-element and read-terminals are suitably insulated from an upper shielding layer or a lower shielding layer.

### BRIEF DESCRIPTION OF THE DRAWINGS

Embodiments of the present invention will now be described by way of examples and with reference to the accompanying drawings, in which:

FIG. 1 is an explanation view of an alumina film forming apparatus used in a method of an embodiment the present invention;

FIG. 2 is a partial sectional view of a thin film magnetic head, in which an alumina film is used as a gap layer;

FIG. 3 is an explanation view of an alumina film produced by the method of the present embodiment; and

FIG. 4 is an explanation view of an alumina film produced by a conventional method.

### DETAILED DESCRIPTION OF THE EMBODIMENTS

Preferred embodiments of the present invention will now be described in detail with reference to the accompanying drawings. In the present embodiment, a production process of a thin film magnetic head of a magnetic disk drive unit, in which a GMR element is used as a read-element, will be explained.

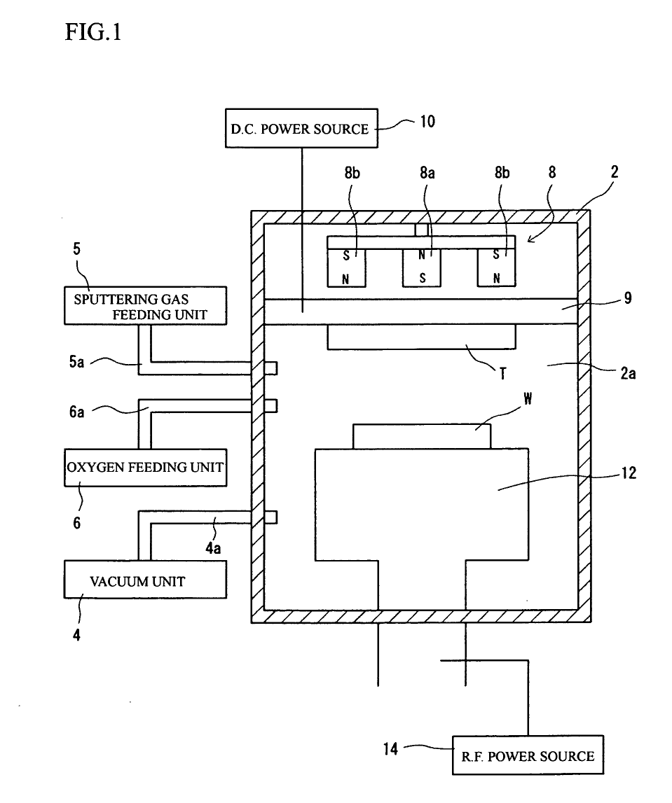

FIG. 1 shows an alumina film forming apparatus A, which produces an alumina film, which is an example of metal-oxide films. The apparatus A comprises: a chassis 2, a vacuum unit 4; a sputtering gas feeding unit 5; an oxygen feeding unit 6; a rotary magnet 8; a target holding section 9; a DC power source 10; a work holding table 12; and a radio-frequency (high-frequency) power source 14.

The chassis 2 is a tightly-closed box, in which a sputtering chamber 2a is formed therein.

The vacuum unit 4 discharges air in the sputtering chamber 2a via a discharge path 4a so as to produce a vacuum state in the sputtering chamber 2a. The sputtering gas feeding unit 5 introduces an argon gas, which is an example of sputtering gasses, into the sputtering chamber 2a via a feeding path 5a. The oxygen feeding unit 6 introduces a gaseous oxygen into the sputtering chamber 2a via a feeding path 6a.

The target holding section 9 is formed into a plate shape and horizontally set in the sputtering chamber 2a. A target T, which is a metal plate, e.g., aluminum plate, is held on a bottom face of the target holding section 9.

The rotary magnet 8 is provided on the opposite side of the aluminum target T with respect to the target holding section 9. Namely, the rotary magnet 8 is provided on the upper side of the target holding section 9 and attached to an inner ceiling face of the sputtering chamber 2a of the chassis 2. A known rotary magnet used for a so-called rotary magnetron sputtering process may be used as the rotary magnet 8. In the rotary magnet 8, a first permanent magnet 8a is located at a position corresponding to a center of the aluminum target T, and an S-pole of the first permanent magnet 8a faces the aluminum target T; a plurality of second permanent magnets 8b are capable of moving around the first permanent magnet 8a in a plane parallel to the plate-shaped aluminum target T, and N-poles of the second permanent magnets 8b faces the aluminum target T.

The DC power source 10 is electrically connected to the target holding unit 9, so that the DC power source 10 is electrically connected to the aluminum target T when the aluminum target T is attached to the target holding unit 9. Therefore, DC positive voltage (plus voltage) can be applied to the aluminum target T. Note that, the DC power source 10 and the chassis 2 are connected to common earth.

The work holding table 12 holds a work W, e.g., wafer, on an upper face thereof so as to make the wafer face the aluminum target T. The work holding table 12 can be moved upward and downward in the sputtering chamber 2a so as to adjust a distance between the aluminum target T and the wafer W.

The radio-frequency (RF) power source 14 is electrically connected to the work holding table 12, so that the RF power source 14 is electrically connected to the wafer W when the wafer W is attached to the work holding table 12. Therefore, RF negative voltage (minus voltage) can be applied to the wafer W. Note that, the RF negative voltage applied is applied to the wafer W in a so-called floating state, in which earth of the RF voltage source 14 is insulated from the common earth of the DC voltage source 10 and the chassis 2.

Next, a method of producing an alumina film, which is an example of metal-oxide films, by an alumina film apparatus and a method of producing a thin film magnetic head will be explained.

Firstly, the aluminum target T, which is a sputtering target, is attached to the bottom face of the target holding section 9, which have been located in the sputtering chamber 2a. The aluminum target T is electrically connected to the DC power source 10 via the target holding section 9.

The wafer W, which is the work, is set on the upper face of the work holding table 12 in the sputtering chamber 2a, so that the wafer W faces the aluminum target T. The wafer W is electrically connected to the RF power source 14 via the work holding table 12.

At that time, facing surfaces of the aluminum target T and the wafer W are arranged nearly parallel, and a distance therebetween is 1.8 inches. The distance between the aluminum target T and the wafer W is adjusted by vertically moving the work holding table 12. Note that, the optimum distance is 1.8 inches so as to make differences between thickness of the alumina film coating edge sections in a surface of the wafer W and that coating flat sections therein small, but the distance is not limited to 1.8 inches. In case of employing the distance of 1.8 inches or less, the thickness difference in the alumina film can be suitably smaller than that in another alumina film formed with the distance of more than 1.8 inches.

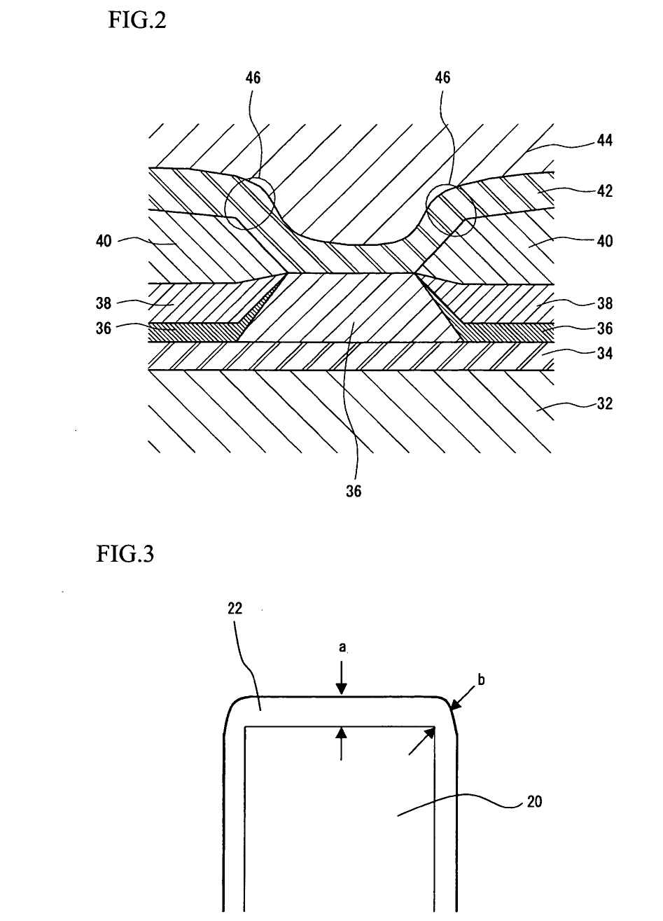

Note that, the wafer W is a substrate of the thin film magnetic head, and a plurality of thin films, e.g., magnetic thin films, will be formed on the wafer W so as to produce the thin film magnetic head shown in FIG. 2.

Alumina films are formed on the wafer W when the gap layer 34 is formed on the lower shielding layer 32 and when the gap layer 42 is formed on the hard films 38 and the read-terminals 40 (see FIG. 2).

Successively, the sputtering chamber 2a is tightly closed, and the vacuum unit 4 is started so as to produce the vacuum state in the sputtering chamber 2a. After the vacuum state is produced in the sputtering chamber 2a and the vacuum unit 4 is stopped, the sputtering gas feeding unit 5 and the oxygen feeding unit 6 are driven so as to introduce the argon gas and the gaseous oxygen into the sputtering chamber 2a.

Then, the rotary magnet 8 is rotated. Further, the DC power source 10 applies DC positive voltage to the aluminum target T, and the RF power source 14 applies RF negative voltage to the wafer W. Therefore, aluminum of the aluminum target T is chemically bonded with oxygen in the sputtering chamber 2a so as to produce alumina, so that an alumina film can be sputtered onto the surface of the wafer W.

Note that, the DC positive voltage applied to the aluminum target T is controlled to make a constant electric power of 3 kW. Further, the RF negative voltage applied to the wafer W is controlled to make a constant electric power of −10 W. Frequency of the RF negative voltage is generally-used frequency, e.g., 13.56 MHz.

In the sputtering process, the target T is made of aluminum, and the sputtering gas, e.g., argon gas, and the gaseous oxygen are introduced so as to form the alumina film in an oxidization mode. Therefore, alumina is deposited onto the surface of the wafer W as a so-called reactive alumina sputtering process. By rotating the rotary magnet 8, a rotary magnetron sputtering process is also performed.

The inventor measured thicknesses of the alumina film produced by the above described method and a comparative alumina film produced by the conventional method disclosed in the Japanese Patent Gazette No. 10-105925. Thicknesses of specific parts of the alumina films, which coat edge sections formed in surfaces of works, were also measured.

Firstly, the alumina film formed on the work by the method of the above described embodiment will be explained.

A cubical projection 20 shown in FIG. 3 was formed in the surface of the work.

After an alumina film 22 was formed on a surface of the projection 20 by the above described sputtering process, a thickness “a” of the alumina film 22, which coated a flat section of the projection 20, and a thickness “b” of the alumina film, which coated an edge section, were measured. The thickness “a” was 5217 Å; the thickness “b” was 3626 Å. Therefore, thickness ratio (b/a) was 70%.

Next, the alumina film formed on the work by the conventional method will be explained.

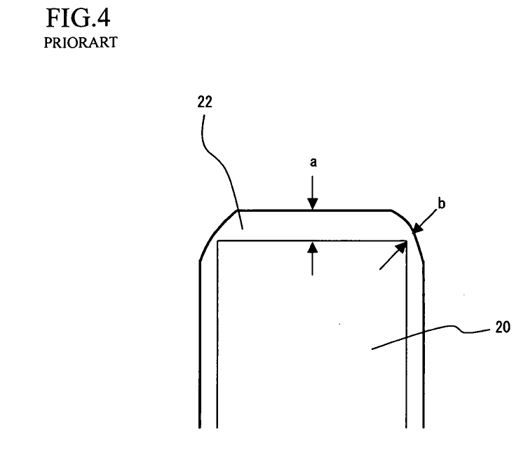

The conventional method was performed under the following conditions. An alumina sputtering target, which was electrically connected to a RF power source, was provided in a closed sputtering chamber. The work, which was electrically connected to the RF power source, was provided in the sputtering chamber and faced the alumina target. Air in the sputtering chamber was discharged, and then an argon gas was introduced in the sputtering chamber. Next, RF positive voltage was applied to the alumina target, and RF positive voltage was applied to the work, so that the alumina film is sputtered onto the surface of the work. A cubical projection 20 shown in FIG. 4 was formed in the surface of the work.

After an alumina film 22 was formed on a surface of the projection 20 by the conventional sputtering process, a thickness “a” of the alumina film 22, which coated a flat section of the projection 20, and a thickness “b” of the alumina film, which coated an edge section, were measured. The thickness “a” was 5478 Å; the thickness “b” was 2055 Å. Therefore, thickness ratio (b/a) was 38%.

Further experiments were performed.

An alumina film was formed by the method of the above described embodiment, wherein RF negative voltage of −30 V was applied to a wafer W. A thickness “a” of the alumina film, which coated a flat section of a projection, and a thickness “b” of the alumina film, which coated an edge section, were measured. The thickness “a” was 5165 Å; the thickness “b” was 3203 Å.

Therefore, thickness ratio (b/a) was 62%. Another alumina film was formed by the method of the above described embodiment, wherein RF negative voltage of −100 V was applied to a wafer W. The thicknesses “a” and “b” were measured as well. The thickness “a” was 5165 Å; the thickness “b” was 2206 Å. Therefore, thickness ratio (b/a) was 43%.

The inventor of the present invention repeated experiments with changing the sputtering conditions. The inventor found that the difference between the thickness “a” and the thickness “b” was suitably reduced when the RF negative voltage, which was applied to the work W, was from −10 V to −1 V.

By employing the method of producing the alumina film of the present embodiment, the thickness of the specific part of the alumina film corresponding to the edge section of the work can be nearly equal to the thickness of the specific part corresponding to the flat section of the work.

Namely, the thickness of the specific part of the alumina film corresponding to the edge section of the work can be made thicker.

By employing the method of producing the thin film magnetic head of the embodiment, the thickness of the specific part of the gap layer (alumina film) corresponding to the edge section of the work can be nearly equal to the thickness of the specific part corresponding to the flat section of the work.

Namely, the thickness of the specific part of the alumina film corresponding to the edge section of the work can be made thicker. Therefore, electric insulation between “an upper shielding layer or a lower shielding layer” and “a read-element and terminals connected to the read-element” can be secured.

The method of producing the alumina film, which is used as the gap layer of the thin film magnetic head, has been described as the preferred embodiment, but the present invention is not limited to the above described embodiment. For example, the method may be applied to form other metal-oxide films of the thin film magnetic head. Besides the thin film magnetic head, the method of the present invention may be applied to form metal-oxide films used in other fields.

The invention may be embodied in other specific forms without departing from the spirit of essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

What is claimed is:

1. A method of producing a metal-oxide film,
comprising the steps of:
introducing a sputtering gas and oxygen into a spattering chamber, in which a metal member and a work are mutually faced; and
applying DC voltage to the metal member and applying high-frequency negative voltage to the work so as to oxidize the metal member and form a sputtered film on a surface of the work.

2. The method according to claim 1,
wherein a distance between facing surfaces of the metal member and the work is 1.8 inches or less.

3. The method according to claim 1,
wherein the high-frequency negative voltage applied to the work is from −10 V to −1 V.

4. The method according to claim 1,
wherein the high-frequency negative voltage applied is applied to the work in a floating state, in which earth of a high-frequency negative voltage source is insulated from those of a DC voltage source and a chassis.

5. The method according to claim 1,
wherein a rotary magnet is provided to a rear surface of the metal member, which is the opposite surface with respect to a surface facing the work, and
the rotary magnet is rotated in said applying step so as to perform a rotary magnetron sputter technique.

6. The method according to claim 1,
wherein a step-shaped section is formed in the surface of the work.
